(19) United States
(12) Patent Application Publication
(10) Pub. No.: US 2024/0271325 A1
(43) Pub. Date: Aug. 15, 2024

(54) MULTILAYER STRUCTURE

(71) Applicant: UNIVERSITETET I OSLO, Oslo (NO)

(72) Inventors: Alexander AZAROV, Oslo (NO); Andrej KUZNETSOV, Oslo (NO); Vishukanthan VENKATACHALAPATHY, Oslo (NO); Calliope BAZIOTI, Oslo (NO)

(21) Appl. No.: 18/616,770

(22) Filed: Mar. 26, 2024

Related U.S. Application Data
(63) Continuation of application No. PCT/EP2022/074243, filed on Aug. 31, 2022.

(30) Foreign Application Priority Data
Mar. 3, 2022 (GR) 20220100195

(51) Int. Cl. C30B 29/68; C30B 29/16; C30B 33/04

(52) U.S. Cl. CPC C30B 29/68; C30B 29/16; C30B 33/04

(57) ABSTRACT

The invention provides a multilayer structure comprising at least two monocrystalline layers A and B, wherein layer A comprises κ-Ga₂O₃ and layer B comprises β-Ga₂O₃ and wherein layers A and B are adjacent

This invention concerns a multilayer structure. In particular, it relates to a multilayer structure comprising at least two monocrystalline layers A and B, wherein layer A comprises κ-Ga₂O₃ and layer B comprises β-Ga₂O₃ and wherein layers A and B are adjacent. The invention also relates to a method of producing κ-Ga₂O₃, said method comprising the step of irradiating β-Ga₂O₃ with an ion beam. The invention further relates to a semiconductor device comprising the multilayer structure.

### BACKGROUND

Polymorphs are common in nature and the basic principles of polymorphism in crystals are known: the lattices adapt to the minimum energy in respect of temperature and pressure. Controllable stabilization of the metastable phases, e.g. at room temperature, is of great interest because it offers the possibility to realise new properties. Certain polymorphs can be stabilized by applying external pressure in materials, however the application of colossal pressures in these scenarios is undesirable. For that reason, reaching metastable conditions via ion beam assisted processes with displaced atoms provoking strain accumulation is an interesting alternative. However, the ion-induced disorder may also result in amorphization, as typically occurs in semiconductors such as Si or SiC. Even for so-called “radiation hard” semiconductors, e.g. GaN or ZnO, the ion irradiation still ends up with high disorder level or partial amorphization.

As a promising ultra-wide bandgap oxide semiconductor material, gallium oxide has potential applications in the wide range of enabling technologies, from power electronics to optoelectronic devices. Ga₂O₃ is well known for its polymorphism, however, at present, Ga₂O₃ fabrication technology is immature. In contrast to the stable β-phase, the metastable Ga₂O₃ polymorphs are not available in the form of bulk crystals of technologically significant size. In order to prepare such polymorphs, film deposition on other Ga₂O₃ substrates is typically employed, utilising strain to facilitate these polymorph formations. For example, CN103924298 describes a method of spontaneous formation of a κ-Ga₂O₃/β-Ga₂O₃ heterogeneous structure. The obtained κ-Ga₂O₃ is a new crystal structure in a gallium oxide system and has orthorhombic symmetry. However, the prepared κ-Ga₂O₃/β-Ga₂O₃ heterogeneous structure comprises merely random inclusions of κ-Ga₂O₃. In the majority of cases, film deposition methods result in inclusions of the second phase, or lead to multiphase growth.

In order to maximise the potential applications of gallium oxide, fabricating regular multi-polymorph structures is of particular interest, paving the way for the realization of polymorph heterostructures. Of specific interest is the attainment of consistent polymorph interfaces, which may be very difficult to fabricate by more-close-to-equilibrium techniques (as all other conventional deposition techniques in comparison to ion implantation) because the growing material will try to inherit the crystalline structure of the substrate.

### SUMMARY OF INVENTION

The present inventors have surprisingly found that ion implantation in gallium oxide can be exploited to generate sufficient strain, triggering the polymorph transitions exactly in the irradiated regions. Unexpectedly, this allows for controllable ion-beam induced phase engineering, resulting in the formation of highly oriented κ-Ga₂O₃ on top of β-Ga₂O₃, not previously achievable by conventional thin film deposition methods. Spectacularly, such fabricated structures, which comprise a layer comprising κ-Ga₂O₃ adjacent to a layer comprising β-Ga₂O₃ exhibit unprecedentedly high radiation tolerance.

Thus, viewed from a first aspect the invention provides a multilayer structure comprising at least two monocrystalline layers A and B, wherein layer A comprises κ-Ga₂O₃ and layer B comprises β-Ga₂O₃ and wherein layers A and B are adjacent.

Viewed from another aspect, the invention provides a method for producing κ-Ga₂O₃, said method comprising the step of irradiating β-Ga₂O₃ with an ion beam.

Viewed from a further aspect, the invention provides a semiconductor device comprising a multilayer structure as hereinbefore defined.

### Definitions

The term “monocrystalline” as used herein means a single crystal phase. Thus, each of the layers in the structures of the present invention may consist of a single crystal phase of gallium oxide, namely layer A comprises gallium oxide in the form κ-Ga₂O₃ and layer B comprises gallium oxide in the form β-Ga₂O₃. This term therefore excludes structures which comprise more than one crystal phase of gallium oxide in a layer.

It will be appreciated that, in the context of the present invention, the terms “film” and “layer” are equivalent and have the same meaning.

### DETAILED DESCRIPTION OF INVENTION

The present invention relates to a multilayer structure comprising at least two monocrystalline layers A and B, wherein layer A comprises κ-Ga₂O₃ and layer B comprises β-Ga₂O₃ and wherein layers A and B are adjacent. The invention also relates to a method for producing κ-Ga₂O₃, said method comprising the step of irradiating β-Ga₂O₃ with an ion beam.

### Multilayer Structure

The multilayer structure of the invention comprises at least two layers A and B as hereinbefore defined. In one embodiment, the structure comprises or consists of two layers, i.e. layer A and layer B. In another embodiment, the structure comprises more than two layers, such as three, four or five layers. In such structures, it is preferable if each of the additional layers is a layer A or B as hereinbefore defined. In one particularly preferred embodiment, the multilayer structure comprises three layers in the order BAB, wherein layers A and B are as hereinbefore defined.

Each layer A and B is monocrystalline. Ideally, each layer is homogenous, i.e. comprising no other phase inclusions.

Layer A comprises, preferably consists of, κ-Ga₂O₃. κ-Ga₂O₃ is a polymorph of gallium oxide with an orthorhombic unit cell.

Layer B comprises, preferably consists of, β-Ga₂O₃. β-Ga₂O₃ is a stable form of gallium oxide and is a polymorph with monoclinic structure.

In all embodiments, it is possible for the gallium oxide to be doped with other metal atoms.

The interface between layers A and B may be considered to be continuous, linear and sharp.

Each layer in the multilayer structure of the invention will typically have a thickness of the order of nanometers or micrometers. The skilled person will appreciate that the thickness of the layers may be tailored towards a particular structure or application. The thickness of the layers may be controlled, for example, by altering the ion energy and/or by the angle of incidence of the ion beam. Thus, each layer may have a thickness in the range of 10 nm to 10 μm, such as 100 nm to 300 nm.

The multilayer structure may form the bulk of the structure or, alternatively, may form part of a more complex structure.

### Method

The methods of the invention comprise irradiating β-Ga₂O₃ with an ion beam. This irradiation produces κ-Ga₂O₃ in a controllable manner.

The ion beam may be any suitable beam of ions which are capable of inducing a sufficiently high level of internal strain within the β-Ga₂O₃, so as to induce the phase transition. Typically, therefore, the ion beam is a medium to heavy ion beam. By “medium to heavy ion beam” we generally mean a beam composed of particles which are heavier than helium. Specific examples of ions which may be employed include nickel, gallium or gold ions.

Typically, the ion beam has a dosage in the range 1×10¹³ to 1×10¹⁷ ions cm⁻² depending on the ion type used. More preferably dosage ranges include 1×10¹⁵ to 1×10¹⁶ ions cm⁻².

The κ-Ga₂O₃ produced by the methods of the invention may form part of any larger overall structure. However, in a preferable embodiment, the κ-Ga₂O₃ forms a layer in a multilayer structure as hereinbefore defined. Hence, the methods of the invention may also be considered as methods of preparing the multilayer structures of the invention.

The κ-Ga₂O₃ produced by the methods of the invention is ideally monocrystalline.

The β-Ga₂O₃ which is irradiated with an ion beam may take any suitable form, such as a single crystal wafer.

The method of the invention preferably does not involve applying external pressure. Typically, the methods may be performed at room temperature (e.g. 18 to 35° C.).

The angle of incidence of the ion beam is an additional option to tune the layer thickness, it can be in the range 0 to 89°.

The multilayer structure of the present invention is particularly applicable for use in a semiconductor device. Thus, the invention also relates to a semiconductor device comprising a multilayer structure as hereinbefore defined. The semiconductor device may find application in a wide range of end uses, such as electronic applications, in particular in high voltage systems in the automotive industry.

The invention will now be described with reference to the following non-limiting examples and figures.

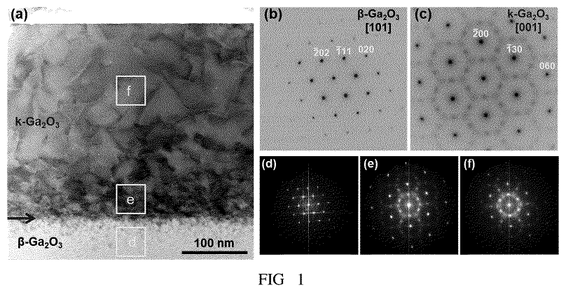

FIG. 1. (a) ABF-STEM image of β-Ga₂O₃ sample irradiated with 1×10¹⁶ Ni/cm². Panels (b) and (c) illustrate SAED patterns from the unimplanted and implanted regions respectively; (d-f) FFTs from high-resolution images taken from different regions of the sample as indicated in the panel (a).

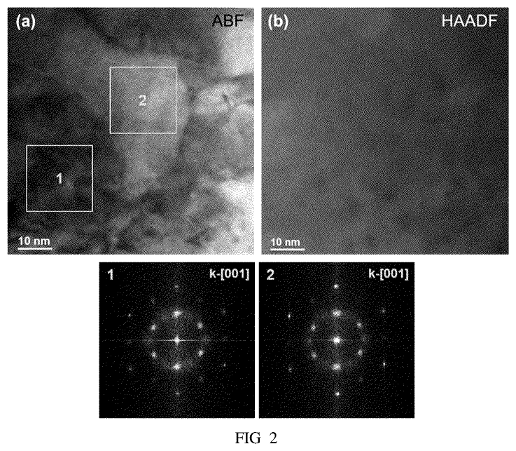

FIG. 2. (a) ABF-STEM and (b) HAADF-STEM high-resolution images acquired simultaneously from the maximum ion-concentration region of (010) β-Ga₂O₃ irradiated with 1×10¹⁶ Ni/cm². FFTs extracted from two adjacent grains, indicated as 1 and 2 in panel (a), are shown in the corresponding bottom panels.

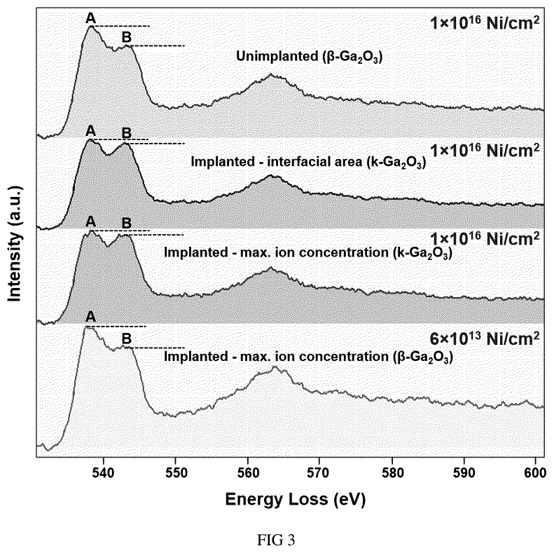

FIG. 3. EELS spectra of the oxygen-K edge, acquired from different areas of the high-dose and low-dose implanted β-Ga₂O₃, illustrating characteristic intensity changes correlated with β-to-κ transition.

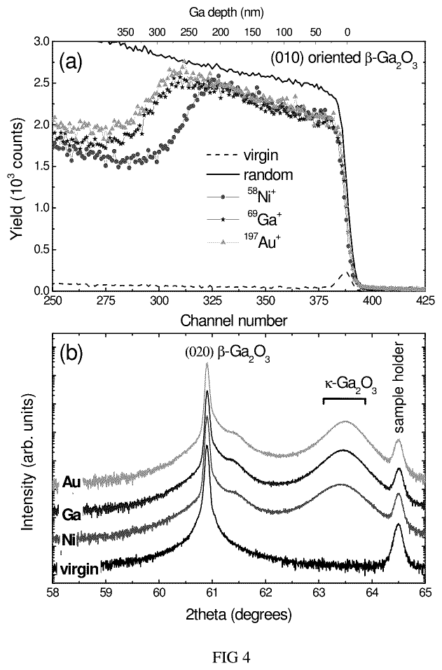

FIG. 4. (a) RBS/C spectra and (b) XRD 2 theta scans of the (010) oriented β-Ga₂O₃ crystals implanted with 400 keV ⁵⁸Ni⁺(1×10¹⁵ cm⁻²), 500 keV ⁶⁹Ga⁺(1×10¹⁵ cm⁻²) and 1.2 MeV ¹⁹⁷Au⁺ ions (3×10¹⁴ cm⁻²).

### EXAMPLES

(010) and (−201) oriented β-Ga₂O₃ single crystal wafers (Tamura Corp.) were implanted with different ions, specifically ⁵⁸Ni⁺, ⁶⁹Ga⁺, and ¹⁹⁷Au⁺. The ballistic defect production rates (without accounting for non-linear cascade density effects) for ⁶⁹Ga⁺ and ¹⁹⁷Au⁺ implants were normalized to that of ⁵⁸Ni⁺ ion implanted with 400 keV in a wide dose range of 6×10¹³ to 1×10¹⁶ cm⁻². The implantations were performed at room temperature (if not indicated otherwise) and 7° off the normal direction.

The samples were analyzed by a combination of Rutherford backscattering spectrometry in channeling mode (RBS/C), x-ray diffraction (XRD) and scanning transmission electron microscopy (STEM) combined with electron energy loss spectroscopy (EELS). The RBS/C was performed using 1.6 MeV He⁺ ions incident along [010] direction and 1650 backscattering geometry. The XRD 2 theta measurements were performed using Bruker AXS D8 Discover diffractometer using Cu K_{α1} radiation in locked-coupled mode.

The STEM and EELS investigations were conducted on an FEI Titan G2 60-300 kV at 300 kV with a probe convergence angle of 24 mrad. The simultaneous STEM imaging was conducted with 3 detectors: high-angle annular dark field (HAADF) (collection angles 101.7-200 mrad), annular dark field (ADF) (collection angles 22.4-101.7 mrad) and annular bright field (ABF) (collection angles 8.5-22.4 mrad). The resulting spatial resolution achieved was approximately 0.08 nm. EELS was performed using a Gatan Quantum 965 imaging filter. The energy dispersion was 0.1 eV/channel and the energy resolution measured using the full width at half maximum (FWHM) of the zero-loss peak was 1.1 eV. Electron transparent TEM samples with a cross-sectional wedge geometry were prepared by mechanical polishing with the final thinning performed by Ar ion milling and plasma cleaning.

Formation of the new phase in β-Ga₂O₃ due to high dose implantation is supported by STEM investigations and FIG. 1(a-f) summarizes the STEM data for the sample implanted with 1×10¹⁶ Ni/cm². Specifically, FIG. 1(a) shows an ABF-STEM image and strain contrast reveals the formation of two distinct regions—the film and the substrate—of the initially homogeneous β-Ga₂O₃ wafer. Selected area electron diffraction (SAED) patterns taken from the unimplanted and implanted regions, i.e. FIGS. 1(b) and 1(c), illustrate a prominent transformation from monoclinic β- to ordered orthorhombic κ-phase. This phase transformation extends to −300 nm from the surface and stops abruptly, forming a sharp interface with the J-phase wafer/substrate, see FIG. 1(a). The contrast associated with defects/strain inside the κ-Ga₂O₃ film gradually increases towards the κ/β interface, see FIG. 1(a). However, fast Fourier transforms (FFTs) from high-resolution images taken at the interfacial area (e) and the upper part (f) of the implanted region show that the ordered orthorhombic phase is retained through the depth of the film as compared with the FFT at the β-Ga₂O₃ substrate, see FIG. 1(f). Thus, SAED and FFTs show the formation of a single-phase ordered orthorhombic κ-phase region both at meso and nano-scale. The sharp spots, in addition to the lack of extra reflections and/or striking of the main reflections, indicate a highly-oriented crystalline film with no signs of high-angle mis-orientations, high-density of mis-oriented grains or amorphization as also supported by FIG. 2 showing an analysis of the adjacent κ-phase grains exhibiting different strain contrast. Indeed, even though the film in FIG. 1(a) was clearly interpreted as single κ-phase film, there are still remaining questions, in particular related to potential mis-orientation between the grains as well as regarding potential chemical variations. For that reason, we investigated two adjacent grains as seen in FIG. 2. FFTs extracted from two adjacent grains reveal that both grains are stabilized in κ-phase and have the same orientation. The stable contrast in HAADF (pure Z-contrast image) indicates no chemical variations and the contrast in ABF is attributed only to the strain. Thus, the grains are nicely co-oriented and there are no chemical inhomogeneities observed.

Moreover, the comparison between EELS spectra in FIG. 3 provides additional arguments. Indeed, because of different atomic coordination in β- and κ-phases we detected characteristic changes in the fine structure of the EELS spectra acquired in STEM-mode, by comparing low and high-dose implanted samples. In particular, the oxygen K-edge is characterized by two main peaks, labelled A and B in FIG. 3, related to the O 2p-Ga 4s and O 2p-Ga 4p bonding, respectively. As seen from FIG. 3, prominent changes in the A/B intensity ratio (I_{A}/I_{B}) occur when the phase transition takes place. Specifically, I_{A}/I_{B} decreases in the x-phase. This can be attributed either to the increase in O 2p-Ga 4p hybridization or to the transfer of electrons from O 2p-Ga 4p band into another band.

The next figure demonstrates that the phenomenon of the β-to-κ phase transition is generically related to the accumulation of the lattice disorder and not to the chemical nature of the implanted ions. This was proved by performing control implants with Ga and Au ions. Note that, the ballistic defect production rates for Ga, and Au implants were normalized to that of Ni ion implanted with 400 keV in a wide dose range of 6×10¹³-1×10¹⁶ cm⁻². FIG. 4 provides a representative example of the corresponding RBS/C and XRD data. As seen from FIG. 4, both the RBS/C profiles and XRD 2 theta scans exhibit very similar trends for the all ion species used. Specifically, FIG. 4(a) shows the formation of the box-shape disorder layer reaching ˜90% of the random signal for the all ions used. In its turn, FIG. 4(b) demonstrates that the virgin β-Ga₂O₃ wafer is characterized by a strong reflection around 60.9° attributed to the (020) planes of β-Ga₂O₃, while the diffraction peaks in the implanted samples centered at ˜63.4° was interpreted as signatures of the κ-Ga₂O₃. Thus, the observed polymorph transitions are attributed to the disorder-induced effects with negligible impact of the chemical nature of the ions.

1. A multilayer structure comprising at least two monocrystalline layers A and B, wherein layer A comprises γ-Ga₂O₃ and layer B comprises β-Ga₂O₃ and wherein layers A and B are adjacent.

2. The multilayer structure as claimed in claim 1, wherein the thickness of the layers is in the range of 10 nm to 10 μm.

3. The multilayer structure as claimed in claim 1, wherein said structure comprises three layers in the order BAB.

4. The multilayer structure as claimed in claim 1, wherein each layer is homogenous.

5. The multilayer structure as claimed in claim 1, wherein the interface between the layers is continuous.

6. A method for producing γ-Ga₂O₃, said method comprising the step of irradiating β-Ga₂O₃ with an ion beam.

7. The method as claimed in claim 6, wherein said ion beam is a medium to heavy ion beam.

8. The method as claimed in claim 6, wherein said γ-Ga₂O₃ is monocrystalline.

9. The method as claimed in claim 6, wherein said γ-Ga₂O₃ forms a layer in a multilayer structure comprising at least two monocrystalline layers A and B, wherein layer A comprises γ-Ga₂O₃ and layer B comprises β-Ga₂O₃ and wherein layers A and B are adjacent.

10. The method as claimed in claim 6, wherein the method does not require applying external pressures.

11. The method as claimed in claim 6, wherein the irradiation takes place at room temperature.

12. The method as claimed in claim 6, wherein said ion beam has a dosage of 1×10¹³ to 1×10¹⁷ ions cm⁻².

13. A semiconductor device comprising a multilayer structure as claimed in claim 1.

14. A multilayer structure prepared by a method which comprises the step of irradiating a β-Ga₂O₃ substrate with an ion beam capable of inducing a phase transition.

15. The multilayer structure prepared by a method as claimed in claim 14, wherein said ion beam is a medium to heavy ion beam.

16. The multilayer structure prepared by a method as claimed in claim 14, wherein said ion beam has a dosage of 1×10¹³ to 1×10¹⁷ ions cm⁻².

17. The multilayer structure prepared by a method as claimed in claim 14, wherein said ion beam comprises nickel, gallium, or gold ions.

18. The multilayer structure prepared by a method as claimed in claim 17, wherein the nickel, gallium or gold ions are selected from ⁵⁸Ni⁺, ⁶⁹Ga⁺ and ¹⁹⁷Au⁺.

19. The multilayer structure prepared by a method as claimed in claim 14, wherein the β-Ga₂O₃ substrate is provided in the form of a (010) or (−201) oriented β-Ga₂O₃ single crystal wafer.
